(19) United States
(12) Patent Application Publication
(10) Pub. No.: US 2025/0185197 A1
(43) Pub. Date: Jun. 5, 2025

(54) DISPLAY DEVICE

(71) Applicant: Samsung Display Co., LTD., Yongin-si (KR)

(72) Inventors: Sang Duk LEE, Yongin-si (KR); Hoi Kwan LEE, Yongin-si (KR)

(73) Assignee: Samsung Display Co., LTD., Yongin-si (KR)

(21) Appl. No.: 18/884,447

(22) Filed: Sep. 13, 2024

(30) Foreign Application Priority Data
Dec. 5, 2023 (KR) 10-2023-0174171

(51) Int. Cl. H05K 5/03; H05K 5/00

(52) U.S. Cl. CPC H05K 5/03; H05K 5/0018

(57) ABSTRACT

A display device includes a display panel, a window member overlapping an upper portion of the display panel and including a main window, a weak adhesive layer, and a protective window in sequence, and a bottom case having a space that houses the display panel and the window member. The weak adhesive layer is a removable adhesive member. The main window is a display device disposed in the space.

### CROSS-REFERENCE TO RELATED APPLICATION(S)

This application claims priority to and benefits of Korean Patent Application No. 10-2023-0174171 under 35 U.S.C. § 119, filed on Dec. 5, 2023 in the Korean Intellectual Property Office, the entire contents of which are incorporated herein by reference.

### BACKGROUND

### 1. Technical Field

This disclosure relates to a display device.

### 2. Description of the Related Art

Display devices are becoming increasingly important with the development of multimedia. These display devices include liquid crystal displays (LCDs) and organic light emitting displays (OLEDs).

Display devices may include a window to protect a display area. Such a window may be made of glass or plastic and may be vulnerable to external impact.

Such windows are often broken from the front and side.

In general, window breakage often requires replacement of the entire display module, not just the window. In this case, users are unable to replace it themselves and there are inconveniences such as visiting a service center.

### SUMMARY

Aspects and features of embodiments of this disclosure provide a display device that allows a user to readily replace only a damaged protective window.

However, aspects of the disclosure are not restricted to those set forth herein. The above and other aspects of the disclosure will become more apparent to one of ordinary skill in the art to which the disclosure pertains by referencing the detailed description of the disclosure provided below.

According to one or more embodiments, a display device may include a display panel, a window member overlapping an upper portion of the display panel and including a main window, a weak adhesive layer, and a protective window in sequence, and a bottom case having a space that houses the display panel and the window member. The weak adhesive layer may be a removable adhesive member. The main window may be a display device disposed in the space.

A bottom surface of the protective window may be disposed in the space. A top surface of the protective window may protrude from a top of the space.

The protective window may have a thickness equal to or thinner than a thickness of the main window.

The thickness of the main window may be in a range of about 0.2 mm to about 0.4 mm. The thickness of the protective window may be in a range of about 0.1 mm to about 0.4 mm.

The window member may further include a light blocking portion formed on a bottom surface of the main window using a material that blocks light.

The display panel may include a display area and a non-display area. The light blocking portion may overlap the non-display area and may not overlap the display area.

The main window and the protective window may be formed of a transparent material. The main window and the protective window may be made of at least one of glass, tempered glass, and plastic.

The main window may be made of resin.

The weak adhesive layer may be made of a pressure sensitive adhesive (PSA). The protective window may be removable by hand.

The display device may further include an adhesive layer between the display panel and the main window. The adhesive layer may have an adhesion that is stronger than an adhesion of the weak adhesive layer.

The window member may have a width wider than a width of the display panel.

The window member may further include a removable auxiliary layer between the weak adhesive layer and the main window, and which may increase slipability by reducing friction.

The removable auxiliary layer may be coated with at least one of a fluorine-based resin and a silicon-based resin.

The display panel may sequentially include a substrate, a circuit driving layer, a light emitting layer, and an encapsulation layer.

The display panel may further include a touch layer and an optical layer on the encapsulation layer.

According to one or more embodiments, a display device may include a display panel, a window member overlapping an upper portion of the display panel and including a main window, a weak adhesive layer, and a protective window in sequence, and a bottom case having a space that houses the display panel and the window member. The bottom case may include a middle frame coupled to the window member, a bottom frame facing a rear side of the middle frame and including a compartment, and a bonding layer between the middle frame and the bottom frame. The weak adhesive layer may be a removable adhesive member. The bonding layer may have an adhesion stronger than an adhesion of the weak adhesive layer.

The main window may be disposed in the space. A bottom surface of the protective window may be disposed in the space. A top surface of the protective window may protrude from the top of the space.

The display device may further include an adhesive layer between the main window and the middle frame. The adhesive layer may have an adhesion stronger than an adhesion of the weak adhesive layer.

The window member may further include a light blocking portion on a bottom surface of the main window including a material that blocks light.

The weak adhesive layer may be made of a pressure sensitive adhesive (PSA). The protective window may be removable by hand.

According to a display device according to embodiments, a user may readily replace only a damaged protective window.

The main window may be disposed inside the case and protected against external impact.

### BRIEF DESCRIPTION OF THE DRAWINGS

FIG. 1 is a schematic perspective view of a display device according to an embodiment of the disclosure.

FIG. 2 is an exploded schematic perspective view of a display device according to an embodiment of the disclosure.

FIG. 3 is a schematic cross-sectional view taken along line A-A′ of FIG. 1.

FIG. 4 is a schematic cross-sectional view illustrating an example of a structure of a sub-pixel included in a display device according to an embodiment of the disclosure.

FIG. 5 is a schematic diagram illustrating a window member including the main window of FIG. 3 and a protective window.

FIG. 6 is a schematic diagram illustrating a window member in which the main window and the protection window of FIG. 5 are combined.

FIG. 7 is a schematic diagram illustrating a window member including a main window and a protective window according to another embodiment of the disclosure.

FIG. 8 is a schematic diagram illustrating a window member in which the main window and the protective window of FIG. 7 are combined.

FIG. 9 is a schematic cross-sectional view taken along line A-A′ of FIG. 1 according to another embodiment.

FIG. 10 is a flowchart schematically illustrating a replacement method for a protective window according to an embodiment.

FIG. 11 is a schematic diagram illustrating steps for preparing a display device that includes a protective window to be replaced in an embodiment.

FIG. 12 is a schematic diagram illustrating the steps of removing the upper protective window to be replaced from the display device of FIG. 11.

FIG. 13 is a schematic diagram illustrating the steps of preparing a new protective window.

FIG. 14 is a schematic diagram illustrating the steps of attaching a new protective window.

### DETAILED DESCRIPTION OF THE EMBODIMENTS

Some embodiments will now be described more fully herein with reference to the accompanying drawings. The embodiments may, however, be provided in different forms and should not be construed as limiting the disclosure. The same reference numbers indicate the same components throughout the disclosure. In the accompanying figures, thicknesses of layers and regions may be exaggerated for clarity.

Description of some parts of embodiments which are not associated with the description may not be provided in order to more clearly describe embodiments of the disclosure.

As used herein, the singular forms, “a,” “an,” and “the” are intended to include the plural forms as well, unless the context clearly indicates otherwise.

It is to be understood that when a layer is referred to as being “on” another layer or substrate, it may be directly on the other layer or substrate, or one or more intervening layers may also be present. When an element is referred to as being “directly on” another element, there may be no intervening elements present.

The phrase “in a plan view” refers to when an object portion is viewed from above, and the phrase “in a schematic cross-sectional view” refers to when a schematic cross-section taken by vertically cutting an object portion is viewed from a side. The terms “overlap” or “overlapped” mean that a first object may be above or below or to a side of a second object, and vice versa. Additionally, the term “overlap” may include layer, stack, face or facing, extending over, covering or partly covering, or any other suitable term as would be appreciated and understood by those of ordinary skill in the art. The expression “not overlap” includes a meaning such as “apart from” or “set aside from” or “offset from” and any other suitable equivalents as would be appreciated and understood by those of ordinary skill in the art. The terms “face” and “facing” mean that a first object may directly or indirectly oppose a second object. In a case in which a third object intervenes between a first object and a second object, the first and second objects may be understood as being indirectly opposed to one another, although still facing each other.

The spatially relative terms “below,” “beneath,” “lower,” “above,” “upper,” or the like, may be used herein for ease of description to describe the relationship between one element or component and another element or component as illustrated in the drawings. It is to be understood that the spatially relative terms are intended to encompass different orientations of the device in use or operation, in addition to the orientation depicted in the drawings. For example, in a case in which a device illustrated in the drawing is turned over, an element positioned “below” or “beneath” another element may be “above” another element. Accordingly, the illustrative term “below” may include both the lower and upper positions. The device may also be oriented in other directions and, thus, the spatially relative terms may be interpreted differently depending on the orientations.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

It is to be further understood that when the terms “comprises,” “comprising,” “has,” “have,” “having,” “includes,” and/or “including” are used, they may specify the presence of stated features, integers, steps, operations, elements, and/or components, but do not preclude the presence or addition of other features, integers, steps, operations, elements, components, and/or any combination thereof.

It is to be understood that, although the terms “first,” “second,” “third,” or the like may be used herein to describe various elements, these elements are not to be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein are inclusive of the stated value and mean within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It is to be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Herein, some example embodiments of the disclosure will be described in further detail with reference to the accompanying drawings.

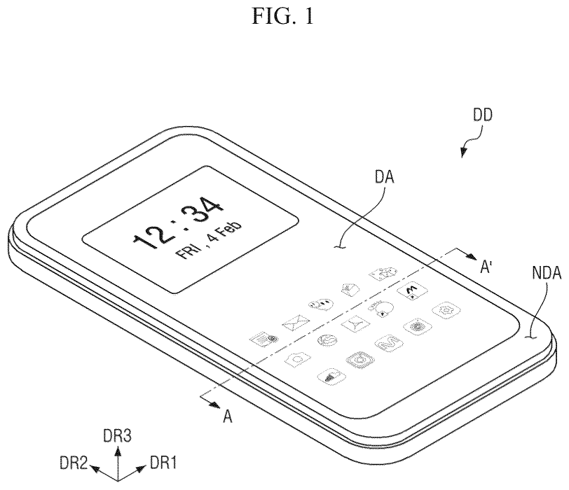

FIG. 1 is a schematic perspective view of a display device according to an embodiment of the disclosure.

A display device DD according to an embodiment is a device for displaying video or still images, such as mobile phones, smart phones, tablet personal computers, and portable electronic devices such as smart watches, watch phones, mobile communication terminals, electronic notebooks, e-books, portable electronic devices such as portable multimedia players (PMP), navigation, and ultra mobile PCs (UMPC), as well as display screens for a variety of products such as televisions, laptops, monitors, billboards, and internet of things (IoT) devices. Furthermore, the display device DD according to an embodiment may be used in a wearable device, such as a smart watch, a watch phone, an eyewear display, and a head mounted display (HMD). In addition, the display device DD according to an embodiment may be used in an instrument panel of an automobile, and as a center information display (CID) disposed on a center fascia or dashboard of an automobile, as a room mirror display in place of a side mirror of an automobile, as entertainment for a rear seat of an automobile, and as a display disposed on the back of a front seat of an automobile. FIG. 1 shows the display device DD being used as a smart phone for convenience of explanation.

In an embodiment, the display device DD may have a rectangular shape including a short side parallel to the first direction DR1 and a long side parallel to the second direction DR2. However, the shape of the display device DD is not limited thereto.

The display device DD may display an image toward the third direction DR3 on a display surface parallel to each of the first direction DR1 and the second direction DR2. The display surface on which the image is displayed may correspond to the front surface of the display device DD. Images may include static images as well as dynamic images.

The display device DD according to an embodiment may detect an externally applied user input. The user's input may include various types of external inputs, such as parts of the user's body, light, heat, or pressure. Further, the display device DD may detect a user's input applied to the side or back of the display device DD depending on the structure of the display device DD.

The front of the display device DD may be divided into a display area DA and a non-display area NDA. The display area DA may be an area where an image is displayed. The user recognizes the image through the display area DA. In this embodiment, the display area DA is shown as a square shape with rounded corners. However, this is shown as an example, and the display area DA may have various shapes and is not limited to any one embodiment.

The non-display area NDA may be disposed on the periphery of the display area DA. The non-display area NDA may be a bezel area. The non-display area NDA may surround the display area DA. However, the disclosure is not limited thereto, for example, the non-display area NDA may not be disposed in at least a portion of the surrounding the display area DA.

Wirings or driving circuits for applying signals to the display area DA (display area or touch area) may be disposed in the non-display area NDA. In another embodiment, the non-display area NDA may include a portion of the touch area, and a sensor member such as a pressure sensor may be disposed in the area.

The display device DD may activate the display screen to display an image and simultaneously detect the user's input. According to an embodiment, an area that detects a user's input may be provided in the display area DA where the image is displayed. However, embodiments are not limited thereto, and the area for detecting the user's input may be provided in the non-display area NDA or may be provided in all areas of the display screen.

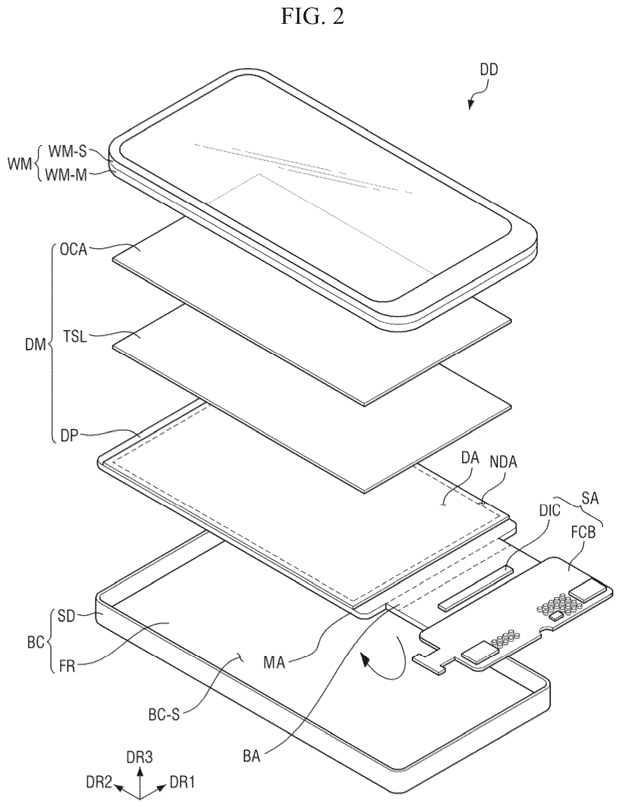

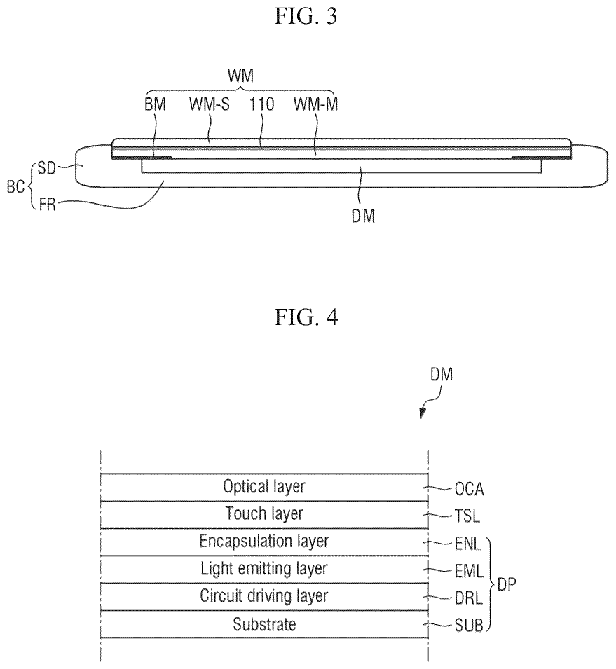

FIG. 2 is an exploded schematic perspective view of a display device according to an embodiment of the disclosure. FIG. 3 is a schematic cross-sectional view taken along line A-A′ of FIG. 1.

Referring to FIGS. 2 and 3, a display device DD may include a display module DM, a window member WM, and a bottom case BC.

The display module DM may include a display panel DP, a touch layer TSL, and an optical layer OCA.

The display panel DP may include pixels. The pixels may be arranged in a matrix direction. The shape of each pixel may be a rectangle or square in plan view, but is not limited thereto. For example, the shape may be a rhombus with each side inclined with respect to the second direction DR2 or the first direction DR1. Each pixel may include a light emitting area. Each light emitting area may be the same shape as the pixel but may also be different. For example, in case that the shape of a pixel is rectangular, the shape of the light emitting area of the pixel may have various shapes, such as rectangular, rhombic, hexagonal, octagonal, circular, etc.

Examples of display panels DP include organic light emitting display panels, micro LED display panels, nano LED display panels, quantum dot light emitting display panels, liquid crystal display panels, plasma display panels, field emission display panels, electrophoretic display panels, electrowetting display panels, and the like. As an example of a display panel DP, an organic light emitting display panel is described below, but embodiments are not limited thereto, and the disclosure may be applied to other display panels as long as the same technical ideas are applied.

The display panel DP may include a flexible substrate containing a flexible polymer material such as polyimide. Accordingly, the display panel DP may be bent, creased, folded, or curled.

The display panel DP may include a bending area BA, which is an area where the panel is bent. Centered around the bending area BA, the display panel DP may be divided into a main area MA located on a side of the second direction DR2 of the bending area BA and a sub-area SA located on another side of the second direction DR2 of the bending area BA.

The display area of the display panel DP may be disposed in the main area MA. In an embodiment, a portion of the peripheral edges of the display area in the main area MA, the entire bending area BA, and the entire sub-area SA may become a non-display area. However, the disclosure is not limited thereto, and the bending area BA and/or the sub-area SA may also include the display area.

The main area MA may have a shape generally similar to the planar outline of the display module DM. The main area MA may be a flat area extending in the first direction DR1 and the second direction DR2. However, the disclosure is not limited thereto, and at least one of the edges of the main area MA, other than the edge connected to the bending area BA, may be curved to form a curved surface or bent in a vertical direction.

The bending area BA may be connected to another side of the main area MA in the second direction DR2. For example, the bending area BA may be connected to the main area MA through the lower end of the main area MA. The width of the bending area BA (width in the first direction DR1) may be smaller than the width of the main area MA adjacent to the bending area BA (width in the first direction DR1). The connection portion between the main area MA and the bending area BA may have an L-shaped cutting shape.

In the bending area BA, the display panel DP may be bent with a curvature downward in the thickness direction, that is, in a opposite direction of the display surface. The bending area BA may have a constant radius of curvature but is not limited thereto and may have a different radius of curvature in different sections. As the display panel DP is bent in the bending area BA, the surface of the display panel DP may be reversed. That is, a side of the display panel DP facing upward may be changed from facing outward through the bending area BA to facing downward again.

The sub-area SA may extend from the bending area BA. The sub-area SA may extend in the direction parallel to the main area MA, starting after the bending is complete. The sub-area SA may overlap the main area MA in the thickness direction of the display panel DP.

A driving chip DIC may be disposed in the sub-area SA. The driving chip DIC may include an integrated circuit for driving the display panel DP. The integrated circuit may include an integrated circuit for the display and/or an integrated circuit for the touch unit. However, the disclosure is not limited thereto, and the display integrated circuit and the touch unit integrated circuit may be provided as separate chips or may be integrated into one chip.

A pad portion may be disposed at an end of the sub-area SA of the display panel DP.

The pad portion may include a plurality of display signal wiring pads and touch signal wiring pads. A driving board FCB may be connected to the pad portion. The driving board FCB may be a flexible printed circuit board or film.

Although FIG. 2 illustrates the bending area BA unfolded without bending, the display panel DP may be stored in the bottom case BC with the bending area BA bent.

The touch layer TSL may be disposed on the display panel DP. In an embodiment, the touch layer TSL may be provided integrally with the display panel DP. However, the disclosure is not limited thereto, and the touch layer TSL may be provided as a separate panel or film from the display panel DP and may be attached to the display panel DP.

The touch layer TSL may include a touch area. The touch area may be an area where touch input is detected. The touch area may overlap the display area DA. That is, the display area DA may be an area where both display and detection of touch input are performed.

The optical layer OCA may be disposed on top of the touch layer TSL but is not limited thereto.

The optical layer OCA may serve to reduce external light reflection. The optical layer OCA may be attached in the form of a polarizing film. In this case, the optical layer OCA polarizes the passing light, and the optical layer OCA may be attached to the top of the touch layer TSL through an adhesive layer. The optical layer OCA in the form of a polarizing film may be omitted. The optical layer OCA may serve to reduce external light reflection.

The window member WM may be disposed on the display module DM. The window member WM may protect the display module DM from external impact. The window WM may have optically transparent properties. The window member WM may be multi-layered.

The window member WM may be arranged to overlap the display panel DP and cover the entire surface of the display panel DP. The window member WM generally may have a similar shape in plan view to the display panel DP but may be larger than the display panel DP. For example, the window member WM may protrude outward from the display panel DP. The planar shape of the window member WM may be the same as that of the display module DM. For example, the planar shape of the window member WM may be substantially circular but is not limited thereto and may have various shapes such as a polygon (e.g., a square or an oval).

The bottom case BC may be disposed at the outermost rear side of the electronic device and may accommodate the display module DM and the window member WM. The bottom case BC may be formed by assembling multiple parts or may include a single injection molded body. The bottom case BC may include a material of at least one of a plastic material, a metal material, and a glass material, and may include a colored coating layer. For example, the bottom case BC according to an example may be flat glass having a transparent, translucent, or opaque color coating layer. Additionally, the bottom case BC may include a glass material with a colored coating layer. This bottom case BC may include a bottom portion FR where the display module DM and the window member WM are accommodated (housed), and multiple side walls SD bent from the bottom portion FR. The space for storage BC-S may be defined by the bottom portion FR and the side walls SD. The side walls SD may surround a portion of the side of the window member WM. A portion of the window member WM may protrude above the side walls SD of the bottom case BC.

In an embodiment, the window member WM may include a double layer. The window member WM may include a main window WM-M and a protective window WM-S.

The main window WM-M may be disposed on top of the display module DM. The protective window WM-S may be disposed on top of the main window WM-M. The protective window WM-S may be disposed farther from the display module DM than the main window WM-M.

The main window WM-M may be completely enclosed in the bottom case BC. For example, the main window WM-M may be disposed in a space BC-S of the bottom case BC. The side of the main window WM-M may be completely enclosed by the side walls SD of the bottom case BC.

A portion of the side of the protective window WM-S may be enclosed by side walls SD. A portion of the protective window WM-S may protrude above the side walls SD of the bottom case BC. A portion of the protective window WM-S may be disposed in the space BC-S of the bottom case BC, and a portion of the protective window WM-S may protrude above the space BC-S.

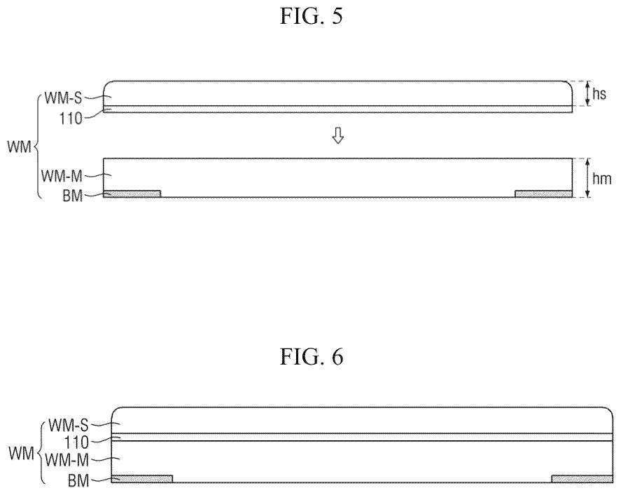

The window member WM will be described in detail with reference to FIGS. 5 and 6.

The display module DM and the main window WM-S may be bonded using a transparent adhesive. The adhesion of the adhesive between the display module DM and the main window WM-S should be better than that of a weak adhesive layer 110.

FIG. 4 is a schematic cross-sectional view illustrating an example of a structure of a sub-pixel included in a display device according to an embodiment of the disclosure.

Referring to FIG. 4, the display panel DP may include a sequentially stacked substrate SUB, a circuit driving layer DRL, light emitting layer EML, and an encapsulation layer ENL. A touch layer TSL and an optical layer OCA may be further disposed on the encapsulation layer ENL, but at least one of the layers may be omitted. The substrate SUB may support components disposed thereon.

The circuit driving layer DRL may be disposed on the substrate SUB. The circuit driving layer DRL may include a circuit that drives the light emitting layer EML of the pixel. The circuit driving layer DRL may include thin film transistors.

The light emitting layer EML may be disposed on the circuit driving layer DRL. The light emitting layer EML may include an organic light emitting layer or an inorganic light emitting layer. The light emitting layer EML may emit light with various brightnesses depending on the driving signal transmitted from the circuit driving layer DRL.

The encapsulation layer ENL may be disposed on the light emitting layer EML. The encapsulation layer ENL may include an inorganic film or a stacked film of an inorganic film and an organic film. In other examples, glass or an encapsulation film may be applied as the encapsulation layer ENL.

The touch layer TSL and the optical layer OCA may be disposed on the encapsulation layer ENL. The touch layer TSL and the optical layer OCA have been described with reference to FIG. 2, so overlapping descriptions will be omitted. In other embodiments, one or more of the touch layers and the optical layer may be omitted.

FIG. 5 is a schematic diagram illustrating a window member including the main window of FIG. 3 and a protective window. FIG. 6 is a schematic diagram illustrating a window member in which the main window and the protection window of FIG. 5 are combined.

Referring to FIGS. 5 and 6, the window member WM may include a main window WM-M, a weak adhesive layer 110, a protective window WM-S, and a light blocking portion BM.

The main window WM-M may overlap the display panel DP and cover the entire surface of the display panel DP. The window member WM may have a shape that is generally similar in plan view to the display panel DP, but its size may be larger than the display panel DP. The width of the main window WM-M in the first direction DR1 and the second direction DR2 may be wider than the width of the display panel DP. For example, the main window WM-M may protrude outward from the display panel DP. The planar shape of the main window WM-M may be the same as that of the display module DM. For example, the planar shape of the main window WM-M may be substantially circular but is not limited thereto and may have various shapes, for example, a polygon such as a square or an oval.

The thickness hm of the main window WM-M may be in a range of about 0.2 mm to about 0.4 mm.

The main window WM-M may be made of a transparent material, such as a plastic material, a glass material, or a tempered glass material. In an example, the main window WM-M may have a stacked structure of any one of sapphire glass and gorilla glass, or a combination thereof. As another example, the main window WM-M may include a material of at least one of polyethyleneterephthalate (PET), polycarbonate (PC), polyethersulfone (PES), polyethylenapthanate (PEN), and polynorborneen (PNB).

In addition, in an embodiment, the main window WM-M may be made of ultraviolet light curing resin, for example, optical clear resin (OCR). The protective window WM-S may overlap the main window WM-M and may protrude outward from the display panel DP. The planar shape of the protective window WM-S may have a similar planar shape to that of the main window WM-M, but the edges may be different. For example, the planar shape of the protective window WM-S may be a rectangle with rounded corners but is not limited thereto.

The thickness hs of the protective window WM-S may be equal to or thinner than the thickness hm of the main window WM-M. The thickness hs of the protective window WM-S may be in a range of about 0.1 mm to about 0.4 mm.

The protective window WM-S may include a synthetic resin film. For example, the protective window WM-S may include, but is not limited to, a polyimide film. The protective window WM-S may include a plastic film as a base layer. The protective window WM-S may include a plastic film as a base layer, such as polyethersulfone (PES), polyacrylate, polyetherimide (PEI), polyethylenenaphthalate (PEN), polyethyleneterephthalate (PET), polyphenylene sulfide (PPS), polyarylate, polyimide (PI), polycarbonate (PC), polyarylene ethersulfone, or a combination thereof. The materials constituting the protective window WM-S are not limited to plastic resins and may include organic/inorganic composite materials. The protective window WM-S may include a porous organic layer and an inorganic material filled in pores of the organic layer. Further, the protective window WM-S may be made of ultra-thin tempered glass or tempered glass material.

The weak adhesive layer 110 may be disposed on the bottom surface of the protective window WM-S. The weak adhesive layer 110 may include a transparent and removable adhesive material. The removable adhesive material may be, for example, a pressure sensitive adhesive (PSA). The pressure sensitive adhesive PSA may be an adhesive in which the adhesive material acts in case that pressure is applied to bond the adhesive to the adhesive surface. The strength of the adhesion may be affected by the amount of pressure that causes the adhesive to be applied to the surface. The removable adhesive material may be used in a variety of ways within the technical idea of the disclosure, but thermosetting resins that are acrylic, silicone, or urethane-based polymers, or adhesives that are thermosetting resins or thermosetting resin UV-curable resins mixed with a crosslinker, or mixtures thereof, or copolymers thereof, may be used.

Since the protective window WM-S is disposed on the main window WM-M, the main window WM-M and the weak adhesive layer 110 may be in direct contact.

A light blocking portion BM may be disposed at the rear of the main window WM-M. The light blocking portion BM may block a portion of the light emitted from the display panel DP. Accordingly, the light blocking portion BM may overlap with the non-display area DA of the display panel DP and may not overlap with the display area DA. The light blocking portion BM may protrude outward from the display panel DP. The light blocking portion BM may be made of black colored resin but is not limited thereto. The light blocking portion BM may be provided in a variety of colored materials that block the progression of light. In other embodiments, the light blocking portion BM may be omitted.

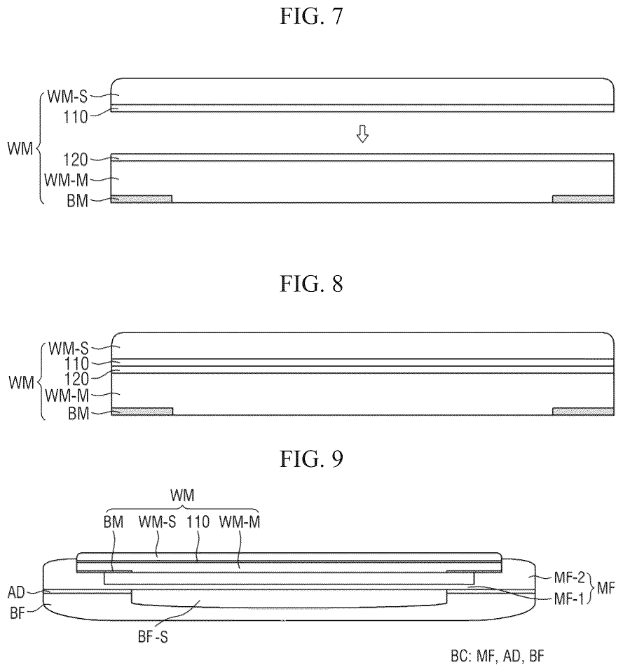

FIG. 7 is a schematic diagram illustrating a window member including a main window and a protective window according to another embodiment of the disclosure. FIG. 8 is a schematic diagram illustrating a window member in which the main window and the protective window of FIG. 7 are combined.

FIG. 7 may be different from the display device according to the embodiment described above with reference to FIGS. 5 and 6 at least in that a removable auxiliary layer 120 for detachment is disposed on the main window member WM-M. Hereinafter, with reference to FIGS. 7 and 8, the differences from FIGS. 5 and 6 will be described.

The removable auxiliary layer 120 may be disposed on the main window WM-M. The weak adhesive layer 110 and the protective window WM-S may be sequentially disposed on the removable auxiliary layer 120. The removable auxiliary layer 120 and the weak adhesive layer 110 may be in direct contact.

The removable auxiliary layer 120 may lower friction and may increase a slip property. The removable auxiliary layer 120 may allow the protective window WM-S to be readily attached and detached from the main window WM-M. The removable auxiliary layer 120 may be formed by depositing titania (TiO₂) or silica (SiO₂) on the main window WM-M and forming a fluorine-based resin or silicone-based resin in an ECC (Easy Cleaning Coating) method. The removable auxiliary layer 120 may more effectively suppress the generation of bubbles in case that the protective window WM-S is attached. Furthermore, the removable auxiliary layer 120 may allow consumers to readily attach and detach the protective window WM-S on their own without any additional tools. Compared to the embodiment in which the removable auxiliary layer 120 is not disposed, the protective window WM-S may be more readily detached from the main window WM-M.

FIG. 9 is a schematic cross-sectional view taken along line A-A′ of FIG. 1 according to another embodiment.

FIG. 9 may be different from FIG. 3 at least in that the bottom case BC may include a middle frame MF and a bottom frame BF. Hereinafter, FIG. 9 will be described in detail with reference to FIG. 3.

The bottom case BC may include a middle frame MF, a bonding layer AD, and a bottom frame BF.

The middle frame MF may serve as a coupling member to join the window member WM and the bottom frame BF. The middle frame MF may be between the window member WM and the bottom frame BF. For example, the middle frame MF may serve as a bracket for fixing.

A display module DM may be between the middle frame MF and the window member WM. The rear surface of the display module DM and the top surface of the middle frame MF face each other but may be spaced apart to provide a compartment between the rear surface of the display module DM and the top surface of the middle frame MF but are not limited thereto. The compartments may store peripheral circuits of electronic devices such as a host driving system, memory, and battery.

The middle frame MF may include a middle plate MF-1 and a middle side wall MF-2.

The middle plate MF-1 may be disposed on the rear of the display module DM. In this case, the middle plate MF-1 may include at least one open portion through which a cable or the like for electrically connecting the display driving circuit connected to the display module DM and the host driving system is passed, and at least one recessed portion through which various electronic circuit components mounted on the electronic device are disposed.

The middle side wall MF-2 may be vertically bonded to the side of the middle plate MF-1 to support the contact surface with the window member WM.

The bonding layer AD may be between the middle frame MF and the bottom frame BF and may bond the middle frame MF and the bottom frame BF to each other. The bonding layer AD may have an adhesive material applied to both sides and may be an adhesive tape with a waterproof or dustproof function. The bonding layer AD has a certain width and is formed along the edge of the middle frame MF. Therefore, the bonding layer AD may correspond to the shape and size of the middle frame MF. That is, if the middle frame MF has a circular shape, the bonding layer AD may also have a circular shape, and if the middle frame MF has a square shape, the bonding layer AD also may have a square shape.

In addition, the bonding layer AD may have a ring shape with a central hole, like the middle frame MF but is not limited thereto. The certain width, if too thick, may expose the middle frame MF to the outside, impairing the aesthetics of the display device (DD in FIG. 1) and obstructing the user's view. Also, if the width is too thin, the adhesion is weakened, and the window member WM and the middle frame MF may be readily separated. Accordingly, the constant width may be formed in various ways depending on the shape and material of the window member WM and the middle frame MF. In practice, the optimal width is experimentally selected to ensure sufficient visibility for the user and sufficient adhesiveness. The bonding layer AD may be formed as a single layer or multiple layers.

The bottom frame BF may be coupled to the side wall MF-2 of the middle frame MF to face the rear of the middle frame MF, covering the rear (or back) of the middle frame MF while providing a compartment BF-S on the rear of the middle frame (MF). The compartment BF-S may be provided below the middle plate MF-1 of the middle frame MF and the bottom frame BF to store the peripheral circuits of electronic devices. Such a bottom frame BF may be detachably coupled to the middle side wall MF-2, for example for battery replacement in the event of a battery discharge during use of the electronic device or may be coupled to the middle sidewall MF-2 to be detachable only upon disassembly for repair of the electronic device. To detachably couple, the bonding layer AD may be omitted and mechanical bonding may be employed. Mechanical bonding may employ various techniques.

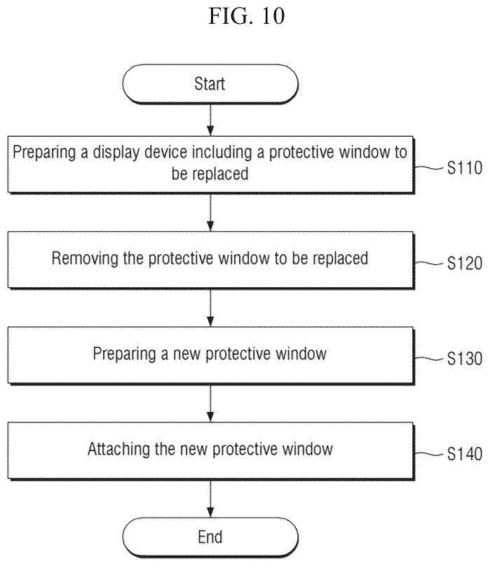

FIG. 10 is a flowchart schematically illustrating a replacement method for a protective window according to an embodiment.

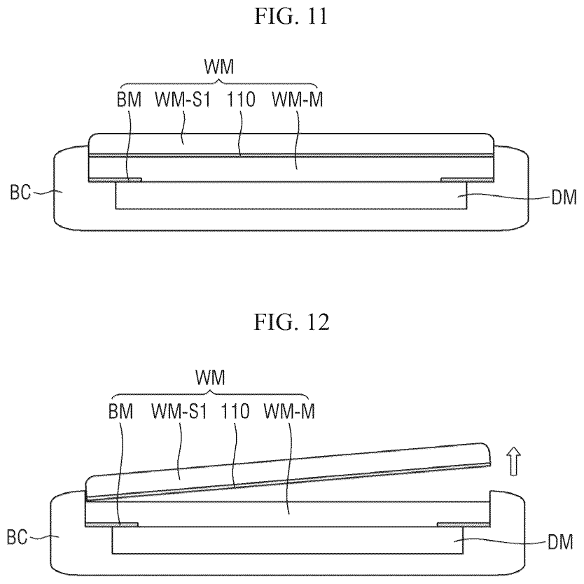

FIGS. 11 to 14 are schematic diagrams illustrating a step of a method for replacing a protective window according to an embodiment. The cross-sectional views of FIGS. 11 to 14 may correspond to the cross-sectional views of the display device of FIG. 3.

Referring to FIGS. 10 to 14, a method of replacing a protective window according to an embodiment may include preparing a display device including a protective window to be replaced (S110), removing the protective window to be replaced (S120), preparing a new protective window (S130), and attaching the new protective window (S140).

FIG. 11 is a diagram illustrating steps for preparing a display device that includes a protective window to be replaced in an embodiment. Referring to FIG. 11, the step S110 of preparing a display device including a protective window to be replaced in an embodiment may include preparing a display device including a window member WM, a display module DM, and a bottom case BC, described with reference to FIGS. 1 to 6, including a protective window WM-S1 to be replaced. Here, the protective window WM-S1 to be replaced may be damaged.

FIG. 12 is a diagram schematically illustrating the steps of removing the upper protective window to be replaced from the display device of FIG. 11. Referring to FIG. 12, the step S120 of removing the protective window WM-S1 to be replaced may include removing the protective window WM-S1 to be replaced from the main window WM-M in the window member WM of the display device DP.

The main window WM-M and the protective window WM-S1 may be adhered by the weak adhesive layer 110, such that the user may readily separate the protective window WM-S1 from the main window WM-M. For example, the user may readily remove the protective window WM-S1 by utilizing a tool such as a scraper or harboring.

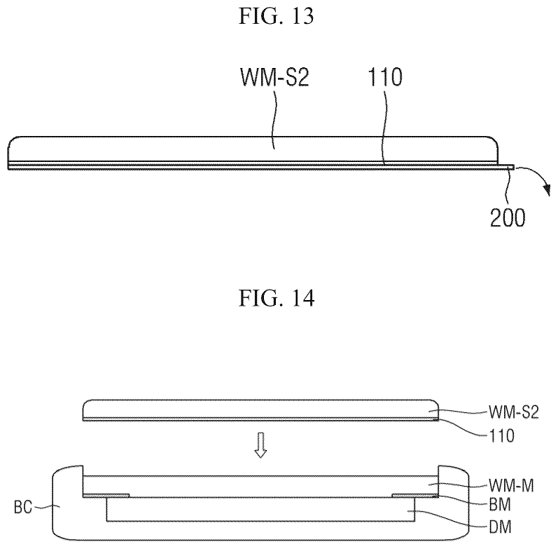

FIG. 13 is a diagram schematically illustrating the steps of preparing a new protective window. Referring to FIG. 13, the step S130 of preparing a new protective window may include preparing a protective window WM-S2 with the weak adhesive layer 110 disposed on the bottom surface.

Since the adhesion of the weak adhesive layer 110 may be reduced if the weak adhesive layer 110 is contaminated, in case that the weak adhesive layer 110 is prepared with the protective film 200 attached to it, the protective film 200 of the weak adhesive layer 110 is peeled off to proceed to the next step.

FIG. 14 is a diagram schematically illustrating the steps of attaching a new protective window. Referring to FIG. 14, the step of attaching a new protective window S140 may include attaching the protective window WM-S2 prepared as shown in FIG. 13 on the main window WM-M of FIG. 12.

The protective window WM-S2 may be adhered to the main window WM-M by the weak adhesive layer 110 disposed on the bottom surface of the protective window WM-S2.

Before providing the protective window WM-S2 on the main window WM-M, it may be desirable to clean the top surface of the main window WM-M of any contaminants. If contaminants are present on the attachment surface, the adhesion may be impaired.

As shown, if a window of a display device is damaged due to an impact or the like, a user may replace only a top layer of the protective window by themselves rather than replacing the entire window. Therefore, user convenience may be improved.

Although some embodiments have been described in the above detailed description, those skilled in the art will appreciate that many variations and modifications can be made to the embodiments without substantially departing from the principles of the disclosure. Therefore, the disclosed embodiments of the disclosure may be understood to be used in a generic and descriptive sense and not for purposes of limitation.

What is claimed is:

1. A display device, comprising:
a display panel;
a window member overlapping an upper portion of the display panel and including a main window, a weak adhesive layer, and a protective window in sequence; and
a bottom case having a space that houses the display panel and the window member, wherein
the weak adhesive layer is a removable adhesive member,
the main window is a display device disposed in the space.

2. The display device of claim 1, wherein
a bottom surface of the protective window is disposed in the space, and
a top surface of the protective window protrudes from a top of the space.

3. The display device of claim 1, wherein the protective window has a thickness equal to or thinner than a thickness of the main window.

4. The display device of claim 3, wherein
the thickness of the main window is in a range of about 0.2 mm to about 0.4 mm, and
the thickness of the protective window is in a range of about 0.1 mm to about 0.4 mm.

5. The display device of claim 1, wherein the window member further comprises a light blocking portion on a bottom surface of the main window including a material that blocks light.

6. The display device of claim 5, wherein
the display panel includes a display area and a non-display area, and
the light blocking portion overlaps the non-display area and does not overlap the display area.

7. The display device of claim 1, wherein
the main window and the protective window are formed of a transparent material, and
the main window and the protective window are made of at least one of glass, tempered glass, and plastic.

8. The display device of claim 1, wherein the main window is made of resin.

9. The display device of claim 1, wherein
the weak adhesive layer is made of a pressure sensitive adhesive (PSA), and
the protective window is removable by hand.

10. The display device of claim 1, further comprising:
an adhesive layer between the display panel and the main window,
wherein the adhesive layer has an adhesion that is stronger than an adhesion of the weak adhesive layer.

11. The display device of claim 1, wherein the window member has a width wider than a width of the display panel.

12. The display device of claim 1, wherein the window member further comprises a removable auxiliary layer between the weak adhesive layer and the main window, and which increases slipability by reducing friction.

13. The display device of claim 12, wherein the removable auxiliary layer is coated with at least one of a fluorine-based resin and a silicon-based resin.

14. The display device of claim 1, wherein the display panel sequentially includes a substrate, a circuit driving layer, a light emitting layer, and an encapsulation layer.

15. The display device of claim 14, wherein the display panel further comprises a touch layer and an optical layer on the encapsulation layer.

16. A display device, comprising:
a display panel;
a window member overlapping an upper portion of the display panel and including a main window, a weak adhesive layer, and a protective window in sequence; and
a bottom case having a space that houses the display panel and the window member, wherein
the bottom case includes:
a middle frame coupled to the window member;
a bottom frame facing a rear side of the middle frame and including a compartment; and
a bonding layer between the middle frame and the bottom frame,
the weak adhesive layer is a removable adhesive member, and
the bonding layer has an adhesion stronger than an adhesion of the weak adhesive layer.

17. The display device of claim 16, wherein
the main window is disposed in the space,
a bottom surface of the protective window is disposed in the space, and
a top surface of the protective window protrudes from a top of the space.

18. The display device of claim 16, further comprising:
an adhesive layer between the main window and the middle frame,
wherein the adhesive layer has an adhesion stronger than an adhesion of the weak adhesive layer.

19. The display device of claim 16, wherein the window member further comprises a light blocking portion on a bottom surface of the main window including a material that blocks light.

20. The display device of claim 16, wherein
the weak adhesive layer is made of a pressure sensitive adhesive (PSA), and
the protective window is removable by hand.
